(19) United States
(12) Patent Application Publication
(10) Pub. No.: US 2025/0362583 A1
(43) Pub. Date: Nov. 27, 2025

(54) STRUCTURE AND METHOD OF SIGNAL ENHANCEMENT FOR ALIGNMENT PATTERNS

(71) Applicant: Taiwan Semiconductor Manufacturing Company, Ltd., Hsinchu (TW)

(72) Inventors: Hsin-Chieh CHEN, Hsinchu (TW); Cheng-Che CHUNG, Hsinchu (TW)

(73) Assignee: Taiwan Semiconductor Manufacturing Company, Ltd., Hsinchu (TW)

(21) Appl. No.: 19/292,036

(22) Filed: Aug. 6, 2025

Related U.S. Application Data
(62) Division of application No. 17/885,870, filed on Aug. 11, 2022.

(51) Int. Cl. G03F 1/42; G03F 1/44

(52) U.S. Cl. CPC G03F 1/42; G03F 1/44

(57) ABSTRACT

In a layout alignment method of a lithographic system for semiconductor device processing, a reference pattern that is included in a reference pattern module is disposed over an alignment pattern of a substrate. The alignment pattern includes two or more sub-patterns that extend in a first interval along a first direction and are arranged with a first pitch in a second direction. Each sub-pattern includes first patterns and second patterns. A width of the first pattern is at least twice as wide as a width of the second pattern. The reference pattern at least partially overlap with the alignment pattern. An overlay alignment error between the reference pattern and the alignment pattern of the substrate is determined. When the overlay alignment error is not more than a threshold value, a photo resist pattern is produced on the substrate based on the layout pattern associated with reference pattern.

### CROSS-REFERENCE TO RELATED APPLICATION

This application is a divisional of U.S. patent application Ser. No. 17/885,870, filed on Aug. 11, 2022, the disclosure of which is incorporated by reference herein in its entirety.

### BACKGROUND

As the semiconductor industry has progressed into nanometer technology process nodes in pursuit of higher device density, reducing overlay errors of a photo resist layout pattern and an underlying layout pattern in a lithography operation has become one of the important issues. Therefore, an efficient method of precisely determining an overlay error between the photo resist layout pattern and one of the underlying layout patterns is desirable.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B respectively illustrate a top view and a cross-sectional view of an alignment pattern to be generated by a light beam lithography system on a wafer in accordance with some embodiments of the present disclosure.

FIGS. 2A and 2B respectively illustrate cross-sectional views of a substrate having two alignment patterns and FIG. 2B further illustrates an optical system for determining an overlay error between the two alignment patterns of the substrate in accordance with some embodiments of the present disclosure.

FIGS. 3A, 3B and 3C respectively illustrate a substrate having two alignment patterns with one alignment pattern having a shift (drift), positive and negative first order diffracted light intensities as a function of the shift, and a difference of the first order diffracted light intensities as a function of the shift.

FIG. 4 illustrates an alignment pattern.

FIGS. 5A, 5B, 5C, and 5D, respectively illustrate a top view of the reference pattern module having two reference patterns, a cross-sectional view of the reference pattern module having two reference patterns, a top view of the reference pattern module having one reference pattern, a cross-sectional view of the reference pattern module having one reference pattern in accordance with some embodiments of the present disclosure.

FIGS. 6A, 6B, and 6C illustrate measurement systems for determining an alignment error in accordance with some embodiments of the disclosure.

FIGS. 7A, 7B, 7C, 7D, and 7E illustrate alignment patterns for determining an overlay error in accordance with an embodiment of the present disclosure.

FIG. 8A, 8B, and 8C illustrate alignment patterns for determining an overlay error in accordance with some embodiments of the disclosure.

FIG. 9 illustrates a measurement system for determining an overlay error in accordance with some embodiments of the disclosure.

FIG. 10 illustrates a flow diagram of a process for determining an overlay error in accordance with some embodiments of the disclosure.

FIGS. 11A and 11B illustrate an apparatus for determining an overlay error in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

During an integrated circuit (IC) design, a number of layout patterns of the IC, for different steps of IC processing, are generated. The layout patterns include geometric shapes corresponding to structures to be fabricated on a wafer. The layout patterns that are projected, e.g., imaged, on the wafer to create the IC may include alignment patterns. A lithography process transfers a layout pattern of a mask to the wafer such that etching, implantation, or other steps are applied only to predefined regions of the wafer. When the layout patterns are transferred, the alignment pattern is also transferred. Multiple layout patterns may be transferred to different layers of the wafer to create the different structures on the wafer. Thus, a second layout pattern may be transferred to a second or subsequent layer on the wafer when a first or previous layout pattern exists in a different first layer of the wafer beneath the second layer. The first alignment pattern transferred to the first layer of the substrate is used for aligning the first layout pattern of the mask to be transferred to the subsequent layer.

As described, multiple layout patterns may be transferred to different layers of the wafer to create the different structures on the wafer. It is ideal that there is no overlay error between the layout patterns that are produced on a wafer. As described, an alignment pattern, e.g., a grating, is included in each layout pattern. The alignment pattern, which may not be part of the IC circuit, is used for determining the overlay error between different layout patterns that are disposed on the wafer. In some embodiments, the overlay error between two alignment patterns of a wafer is measured when the alignment patterns of the two layout patterns overlap. The overlapped alignment patterns of the two layout patterns are irradiated with a beam of light, e.g., a coherent beam of light, and the overlay error between two layout patterns is determined, e.g., calculated, based on diffracted light that is reflected back from the overlapped alignment patterns of the two layout patterns.

In some embodiments, a first layout pattern that includes a first alignment pattern is imaged, e.g., projected, onto a wafer such that the first layout pattern and the first alignment pattern is produced in a first layer on the wafer. In some embodiments, the first layer is covered with a second layer and a second layout pattern that includes a second alignment pattern is created in the second layer. The second layer is initially covered with a resist material layer and the second layout pattern that includes the second alignment pattern is imaged onto the resist material layer on top of the second layer. Therefore, the second alignment pattern is in the resist material layer and the resist material layer is on top of the second layer that is on top of the first layer, which includes the first alignment pattern. In some other embodiments, the second layer does not exist and the first layer is covered with the resist material layer and the second layout pattern that includes the second alignment pattern is imaged onto the resist material layer that is directly on top of the first layer. Therefore, the second alignment pattern is in the resist material layer and the resist material layer is on top of the first layer, which includes the first alignment pattern. In either case, after the resist material is developed, if the first alignment pattern of the first layer and the second alignment pattern of the resist material layer on top of the first layer overlap, the overlay error between the first layout pattern and the second layout pattern may be measured. In some embodiments, when the overlay error is below a threshold, the developed resist material that includes the second layout pattern is used in the next processing step. Otherwise, the resist material is removed and a new resist layout pattern is formed with corrected alignment in the lithography process. In some embodiments, the first layer that covers the first alignment pattern is a metal layer, e.g., an electric connection line or an electrode, and the second layer is an oxide layer.

As noted, the overlay error may be measured when the first alignment pattern of the first layer and the second alignment pattern of the resist material layer overlap. In some embodiments, each one of the layout patterns includes an alignment pattern to make sure overlap happens in at least one location that produces a strong diffracted light that is reflected back from the overlapped alignment patterns. In some embodiments, a reference pattern module including one or more reference patterns is disposed on the wafer. Instead of overlapping the alignment pattern of the resist material layer with the alignment pattern of a layer beneath the resist material layer to determine the overlay error, the overlay error of each layer of the substrate, including the resist material layer, is determined with respect to the reference pattern module. Therefore, an overlap between the alignment patterns of the resist material layer and a layer beneath the resist material layer is avoided and, also, multiple alignment patterns in the layout pattern of a layer may be avoided.

In some embodiments, the reference pattern module incudes one or more, e.g., two, reference patterns that are disposed in the reference pattern module. The location of the reference patterns to each other and/or to a reference point on the reference pattern module is predetermined.

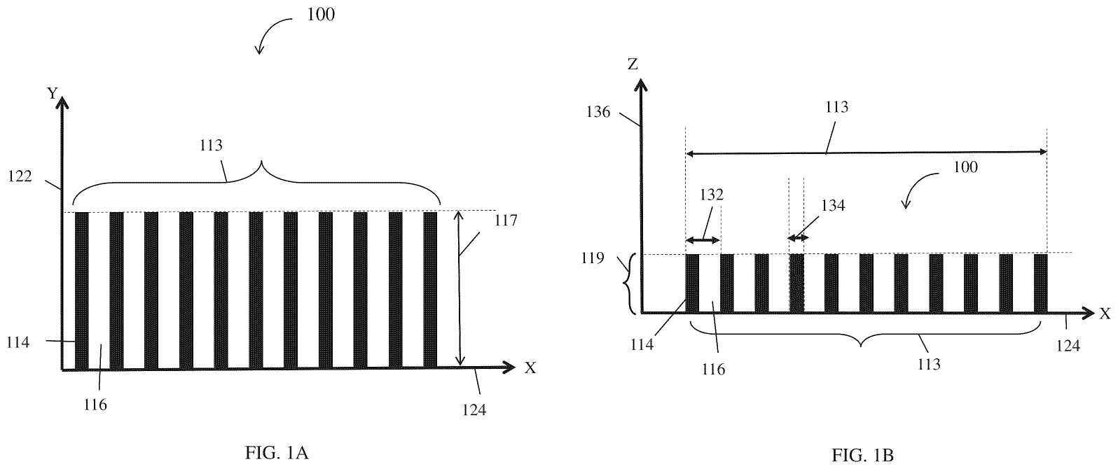

FIGS. 1A and 1B respectively illustrate a top view and a cross-sectional view of an alignment pattern to be generated by a light beam lithography system on a wafer in accordance with some embodiments of the present disclosure. FIG. 1A shows an alignment pattern 100 that is extended in a Y-direction 122 with a length 117 and is distributed in an X-direction 124 in an extent 113. The alignment pattern 100 includes dark strips 114 and bright strips 116. In some embodiments, dark strips 114 are low reflectance portions and the bright strips 116 are high reflectance portions when an incident light beam radiates the alignment pattern 100.

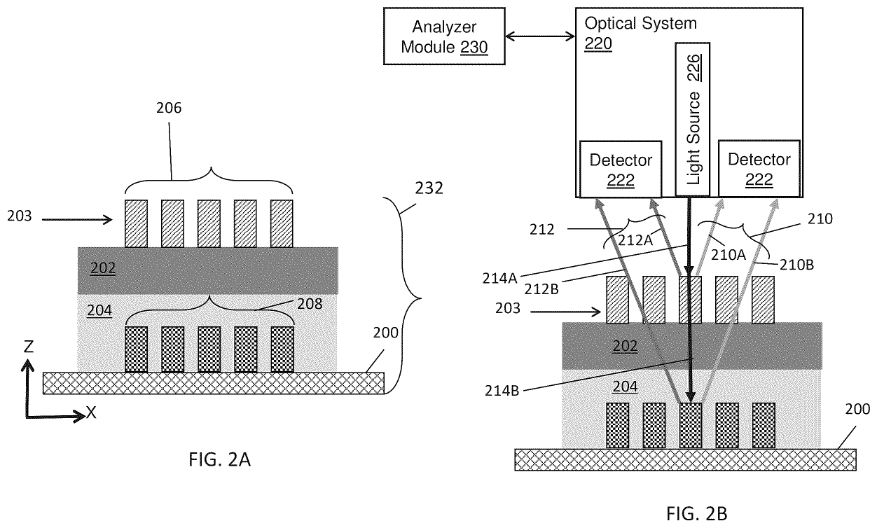

FIG. 1B shows a cross-sectional view of the alignment pattern 100 that is extended in a Z-direction 136 with a height 119 and is distributed in the X-direction 124. In some embodiments, the dark strips 114 are the features of a layer (e.g., a photo resist pattern) that remain after a lithography process is applied and the bright strips 116 are the locations that are removed after the lithography process is applied. In other embodiments, the dark patterns and the bright patterns are reversed depending on, for example, a material of the underlying layer. As shown in the cross-sectional view, the dark strips 114 have a width 134, e.g., critical dimension (CD), and the alignment pattern 100 has a pitch 132 in the X-direction. In some embodiments, when a wavelength of the incident light beam is comparable with the width 134 and/or the pitch 132 of the alignment pattern, the incident light beam is diffracted and a portion of the incident light beam is reflected back. The diffraction of the incident light beam is described with respect to FIG. 2B.

FIGS. 2A and 2B respectively illustrate cross-sectional views of a substrate 232 having two alignment patterns 206 and 208. FIG. 2B further illustrates an optical system 220 for determining an overlay error between the two alignment patterns of the substrate in accordance with some embodiments of the present disclosure. FIG. 2A includes a cross-sectional view of an alignment pattern 208 in a first layer 204 that is disposed on top of an underlying substrate 200. In some embodiments, the alignment pattern 208 along with a corresponding circuit layout pattern (not shown) is initially disposed on the underlying substrate 200 and then the first layer 204 is disposed, e.g., epitaxially grown or deposited, over the alignment pattern 208. In some embodiments, a second layer 202 is disposed, e.g., epitaxially grown or deposited, over the first layer 204. In some embodiments, a resist layer 203 is deposited over the second layer 202 and the resist layer 203 is exposed and developed to produce an alignment pattern 206 along with a corresponding layout pattern (not shown) in the resist layer 203. In some embodiments, the alignment patterns 206 and 208 are consistent with the alignment pattern 100 of FIGS. 1A and 1B. Also, consistent with FIGS. 1A and 1B, the alignment patterns 206 and 208 are distributed in the X-direction to measure an overlay error in the X-direction. In some embodiments, alignment patterns distributed in the Y-direction are also disposed to measure an overlay error in the Y-direction. In some embodiments, the second layer 202 does not exist and the alignment pattern 206 is disposed on top of the first layer 204. In some embodiments, a substrate 232 includes the underlying substrate 200 and a structure including the first layer 204, the second layer 202, and the resist layer 203, on top of the underlying substrate 200. In some embodiments, the first layer 204 is a metal layer, e.g., connection lines or electrodes, and the second layer 202 is an oxide layer, e.g., silicon oxide.

FIG. 2B shows an optical system 220 that includes one or more light sources 226 and one or more detectors 222. FIG. 2B further shows the alignment patterns 206 and 208 and the first layer 204, the second layer 202, and the resist layer 203. In some embodiments, a light source 226 of the optical system 220 transmits, e.g., radiates, an incident light beam 214A to the alignment patterns 206 and 208 that have an overlap in the X-direction and in the Y-direction. In some embodiments, the alignment patterns 206 and 208 have a same pitch and the light source 226, which is a coherent light source, has a wavelength comparable to the pitch of the alignment patterns 206 and 208. A portion of the incident light beam 214A is diffracted and reflected from the alignment pattern 206 and produces the negative and positive first order reflected diffraction beams 210A and 212A respectively. A remaining portion 214B of the incident light beam 214A passes through the alignment pattern 206 and is diffracted and reflected from the alignment pattern 208 and produces the negative and positive first order diffraction beams 210B and 212B respectively. Thus, the first order reflected diffraction beams 210 that includes the negative first order reflected diffraction beams 210A and 210B that are reflected are detected by one detector 222 and the first order reflected diffraction beams 212 that includes the positive first order reflected diffraction beams 212A and 212B that are reflected and are detected by another detector 222. As shown, a pattern is produced in the second layer 202, which is an oxide layer on top of the first layer 204, which is a metal layer. In some embodiments, the first layer 204 of metal is opaque, e.g., at least semi-opaque, to the negative and positive first order diffraction beams 210B and 212B.

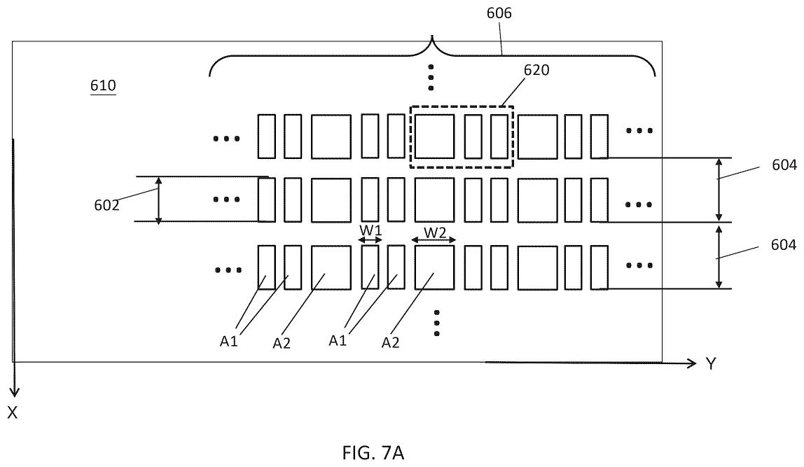

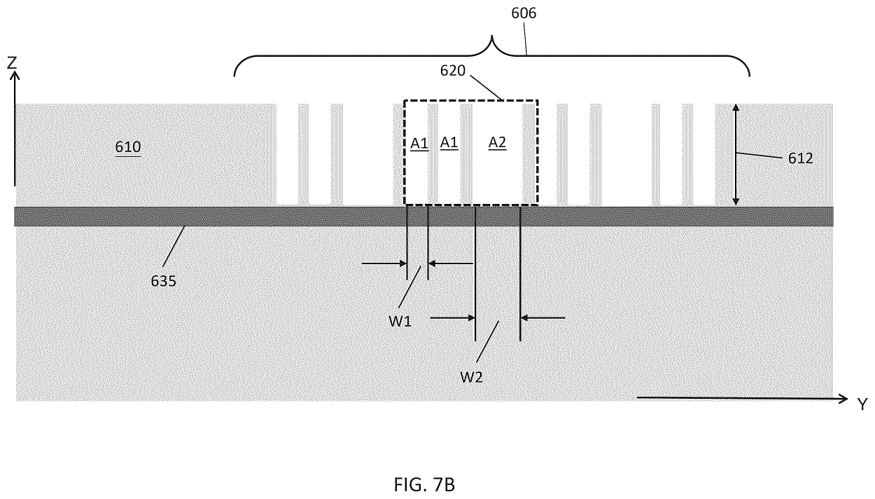

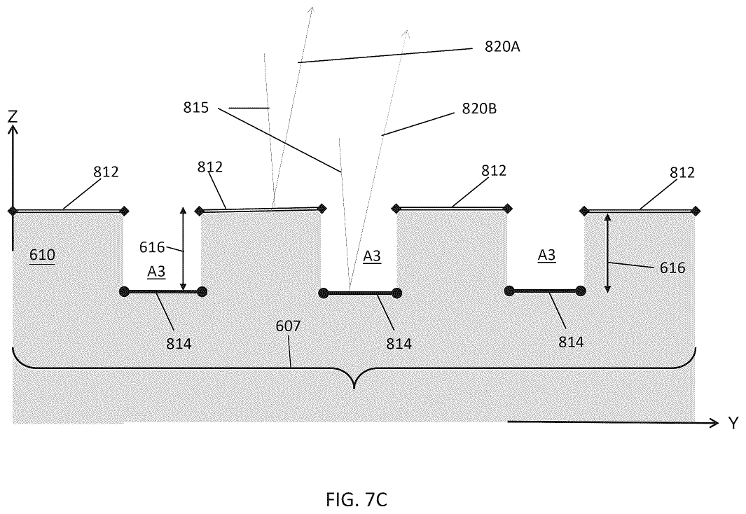

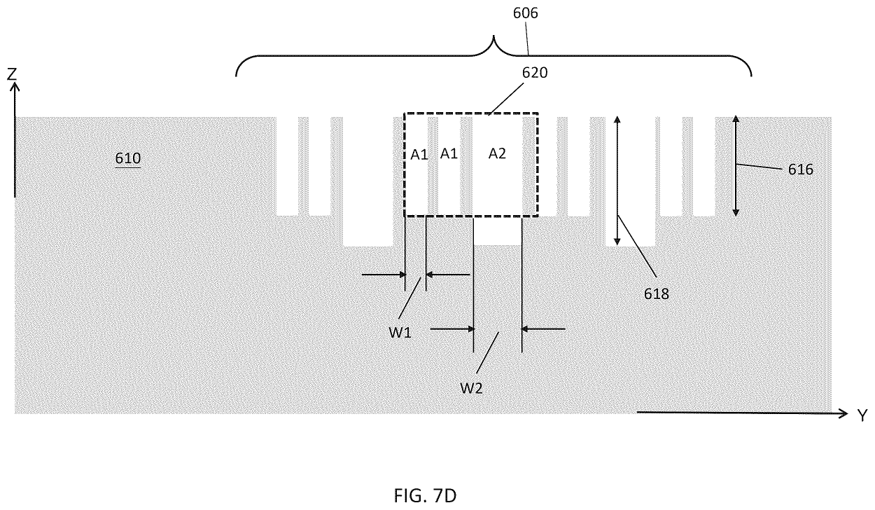

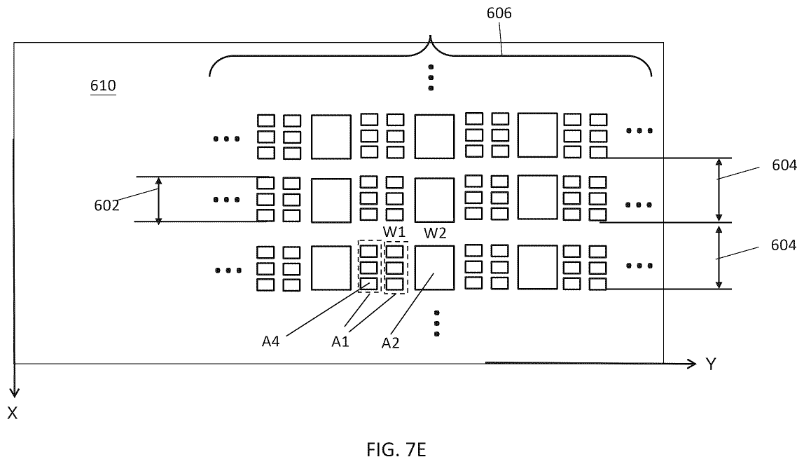

An analyzer module 230 shown in FIG. 2B is coupled to the optical system 220. The analyzer module 230 receives corresponding signals of the detected first order reflected diffraction beams 210 and 212 and performs an analysis on the corresponding signals to determine a drift, e.g., a shift, between the alignment patterns 208 and 206. The structure of the alignment patterns 206 and 208 are described with respect to FIGS. 7A, 7B, 7D, and 7E.

In some embodiments, the first layer 204 includes the alignment pattern 208 as a portion of a first layout pattern. Also, the resist layer 203 that is deposited on the second layer 202 includes the alignment pattern 206 as a portion of a second layout pattern. Thus, the lateral positional difference between the alignment patterns 208 and 206 indicates the lateral positional difference between the first layout pattern of the first layer 204 and the second layout pattern to be created in the second layer 202 using the resist layer 203. In some embodiments, the top alignment pattern 206 and the bottom alignment pattern 208 have the same pitch and the same shape such that the number of boxes (e.g., sub-patterns of the alignment pattern), the width of the boxes, and the distance between the boxes in the alignment patterns 206 and 208 are the same. In some embodiments, the top alignment pattern 206 and the bottom alignment pattern 208 coincide such that the boxes in the alignment patterns 206 and 208 coincide and there is no drift between the boxes of the top alignment pattern 206 and the boxes of the bottom alignment pattern 208. In some embodiments, due to the numerical aperture of the optical system 220, (e.g., due to the numerical aperture of the detectors 222,) the first order reflected diffraction beams 210A and 212A enter the detectors and the higher order diffraction beams do not enter the optical system 220.

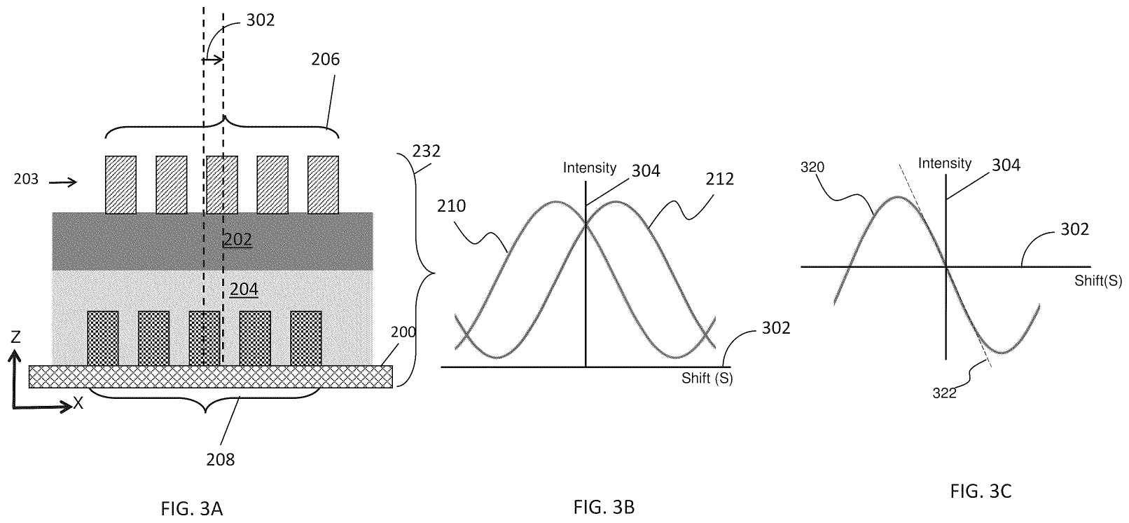

FIGS. 3A, 3B and 3C respectively illustrate a substrate 232 having two alignment patterns 206 and 208 with one alignment pattern having an overlay shift (FIG. 3A), negative and positive first order reflected diffraction beams 210 and 212 as a function of the overlay shift (FIG. 3B), and a difference of the first order diffracted light intensities as a function of the overlay shift distance 302 (FIG. 3C) in accordance with some embodiments of the present disclosure. FIG. 3A is consistent with FIG. 2A with a difference that the alignment pattern 206 of the resist layer 203 on top of the second layer 202 is shifted with respect to the alignment pattern 208 by a shift distance 302 in the positive X-direction. The shift distance 302 is a distance between the center (e.g., the center of mass or the center of the center pattern) of the two alignment patterns 206 and 208.

FIG. 3B shows light intensities of the negative and positive first order reflected diffraction beams 210 and 212 as a function of overlay shift distance 302. In some embodiments, FIG. 3B respectively shows the signals corresponding to the negative and positive detected first order reflected diffraction beams 210 and 212 that are detected by detectors 222 of the optical system 220 in FIG. 2B. In some embodiments, the analyzer module 230 receives corresponding signals of detected first order reflected diffraction beams 210 and 212 and subtracts the signal corresponding to the negative first order reflected diffraction beams 210 from the signal corresponding to the positive first order reflected diffraction beams 212 to generate an asymmetry (AS) function 320 (FIG. 3C). As shown in FIG. 3B, the signal corresponding to the negative first order diffraction 210 has an intensity peak in the negative region of the shift distance 302 and the signal corresponding to the positive first order diffraction 212 has an intensity peak in the positive region of the shift distance 302. Also, FIG. 3B shows that the signals corresponding to the negative and positive detected first order reflected diffraction beams 210 and 212 are symmetric with respect to the intensity coordinate 304. Although the shift distance 302 is displayed as the shift between the edges of the boxes of the alignment patterns 206 and 208, the origin of the alignment patterns 206 and 208 may be defined as the center of the alignment patterns 206 and 208 and the shift distance 302 can be defined with respect to a shift in the center of the alignment patterns 206 and 208.

FIG. 3C shows the AS function 320 as a function of the shift distance 302. Because the signals corresponding to the negative and positive detected first order reflected diffraction beams 210 and 212 are symmetric with respect to the intensity coordinate 304, the AS function 320 passes through the origin. In some embodiments, the AS function may be written as:

$$AS = k \cdot sin [ ( \frac{2 Π}{P} ) \cdot ( S ) ]$$

where P is a pattern (grating) pitch, S is the shift distance 302, and k is determined based on the light wavelength and a layer structure (e.g., thickness, refractive index, and absorption coefficient) of the first layer, the second layer, and the resist material layer. In some embodiments, when the shift distance 302 is small compared to the pattern pitch P, the AS function may be written as:

$$AS = k \cdot ( \frac{2 Π}{P} ) \cdot ( S )$$

where

$$K = k \cdot ( \frac{2 Π}{P} )$$

is the slope 322 of the AS function 320 at the origin in FIG. 3C.

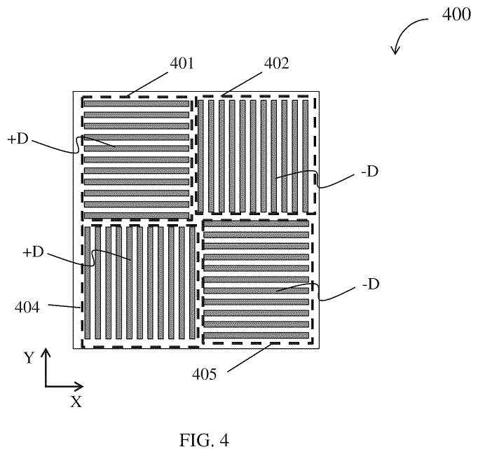

FIG. 4 illustrates an alignment pattern in accordance with an embodiment of the present disclosure. The alignment pattern 400 of FIG. 4 that may be used as the alignment pattern 206 and may be produced in the resist material layer 203 has four different alignment patterns. In some embodiments, when the alignment pattern 400 on the top coincides with the bottom alignment pattern 208, the upper right portion 402 and the lower left portion 404 of the alignment pattern 400 respectively have an initial shift of −D and +D in the positive X-direction with respect to the bottom alignment pattern 208. In some embodiments, the alignment pattern 400 on the top is placed with an X-direction overlay error OV, e.g., overlay placement error in the X-direction, over the bottom alignment pattern 208 and thus the AS function between the upper right portion 402 and the bottom alignment pattern 208 becomes:

$$A S 1 = k \cdot sin [ ( \frac{2 Π}{P} ) \cdot ( OV - D ) ]$$

which is a point on the AS function 320 of FIG. 3C with a shift S=(OV−D). The AS function between the upper right portion 402 and the bottom alignment pattern 208 may be approximated as AS1=K.(OV−D), which is a point on the slope 322 of the AS function 320 of FIG. 3C with the shift S=(OV−D). Also, the AS function between the lower left portion 404 and the bottom alignment pattern 208 becomes:

$$A S 2 = k \cdot sin [ ( \frac{2 Π}{P} ) \cdot ( OV + D ) ]$$

which is a point on the AS function 320 of FIG. 3C with a shift S=(OV+D). The AS function between the lower left portion 404 and the bottom alignment pattern 208 may be approximated as AS2=K.(OV+D), which is a point on the slope 322 of the AS function 320 of FIG. 3C with the shift S=(OV+D). Thus, by using the optical system 220 of FIG. 2B and measuring the negative and positive detected first order reflected diffraction beams 210 and 212, the AS function value AS1 between the upper right portion 402 of the alignment pattern 400 and the bottom alignment pattern 208 and the AS function value AS2 between the lower left portion 404 of the alignment pattern 400 and the bottom alignment pattern 208 can be determined and the overlay error OV in the X-direction may be determined as:

$$O V = D \cdot ( \frac{AS 1 + AS 2}{AS 2 - AS 1} )$$

In some embodiments, when the alignment pattern 400 on the top coincides with the bottom alignment pattern 208, the upper left portion 401 and the lower right portion 405 of the alignment pattern 400 respectively have an initial shift of −D and +D in the positive Y-direction with respect to the bottom alignment pattern 208. Thus, the overlay error in the Y-direction may similarly be determined.

In some embodiments and as shown in FIGS. 1A and 1B, an extent 113 of each portion of the alignment pattern 400 is between 300 nm and 40,000 nm. A CD of the sub-patterns, e.g., boxes, of each portion of the alignment pattern 400 is between 10 nm and 1400 nm. A pitch between the sub-patterns of each portion of the alignment pattern 400 is between 100 nm and 1500 nm.

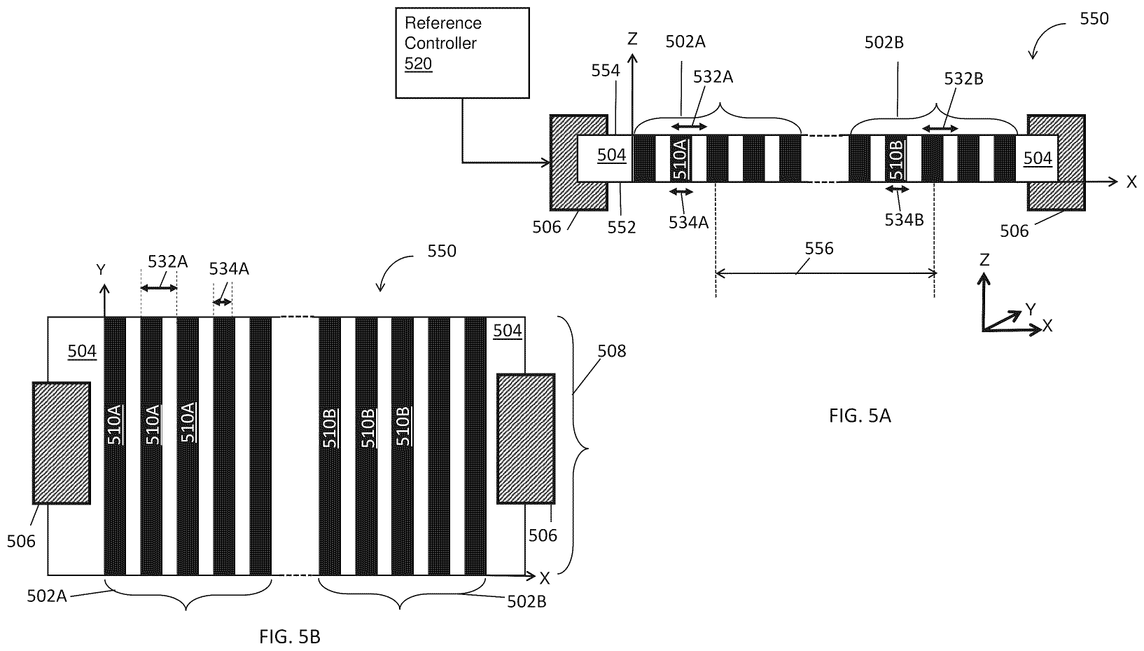

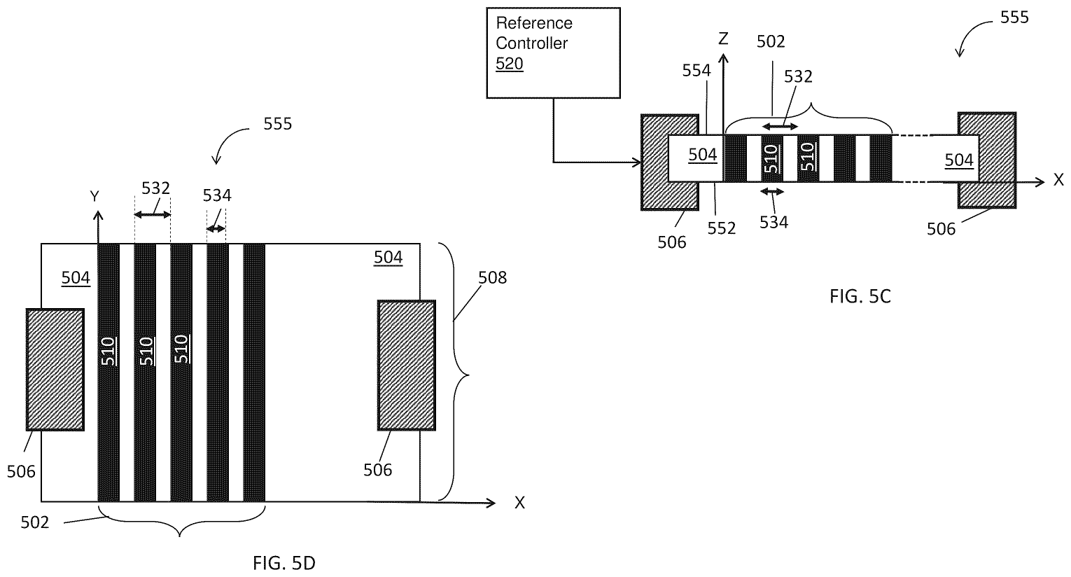

FIGS. 5A, 5B, 5C, and 5D, respectively illustrate a top view of the reference pattern module having two reference patterns, a cross-sectional view of the reference pattern module having two reference patterns, a top view of the reference pattern module having one reference pattern, a cross-sectional view of the reference pattern module having one reference pattern in accordance with some embodiments of the present disclosure. FIG. 5A is a cross-sectional view of a reference pattern module 550 with a layer 504 having a top surface 554 and a bottom surface 552. The reference pattern module 550 includes two reference patterns 502A and 502B arranged in the X-direction. The reference pattern 502A includes, disposed in the layer 504, sub-patterns 510A and the reference pattern 502B includes the sub-patterns 510B that are disposed in the layer 504. In some embodiments, the sub-patterns 510A and 510B are produced by patterning the layer 504, etching a location of the sub-patterns 510A and 510B, and then depositing a material different from a material of layer 504 in the etched regions. In some embodiments, dark sub-patterns 510A and 510B are low reflectance portions and the bright boxes neighboring the sub-patterns 510A and 510B are high reflectance portions when an incident light beam radiates the reference patterns 502A and 502B. As shown, a reference controller 520 is coupled to the reference pattern module 550 to move the reference pattern module 550 in the X, Y, or Z directions. FIG. 5B show a top view of the reference pattern module 550. In some embodiments, the reference patterns 502A and 502B have a center-to-center distance 556 between the reference patterns 502A and 502B. In some embodiments, the reference patterns 502A and 502B are not adjacent to each other. In some embodiments, the sub-patterns 510A (e.g., boxes) of the reference pattern 502A have a width 534A and a pitch 532A and the sub-patterns 510B (e.g., boxes) of the reference pattern 502B have a width 534B and a pitch 532B. In some embodiments, the reference pattern module 550 is held in place with supporting fixtures 506.

FIG. 5B is a top view of the reference pattern module 550 and shows the reference patterns 502A and 502B disposed in the layer 504 of the reference pattern module 550. In some embodiments, the sub-patterns 510A have a uniform width 534A and/or the sub-patterns 510B have a uniform width 534B and the width 534A is different from the width 534B. In some embodiments, the reference pattern 502A has a uniform pitch 532A between each two neighboring sub-patterns 510A and/or the reference pattern 502B has a uniform pitch 532B between each two neighboring sub-patterns 510B and the pitch 532A is different from the pitch 532B. In some embodiments, the reference pattern module 550 has a length 508 in the Y-direction.

FIGS. 5C and 5D respectively show cross-sectional view and top view of a reference pattern module 555 that is consistent with the reference pattern module 550 with the difference that reference pattern module 555 has one reference pattern 502. The reference pattern 502 has sub-patterns 510 with a width 534, a pitch 532, and a length 508.

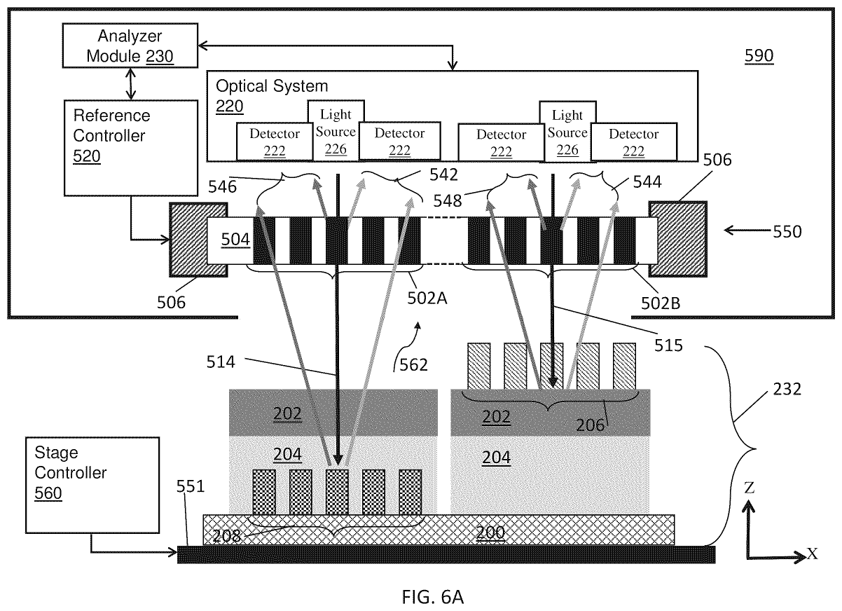

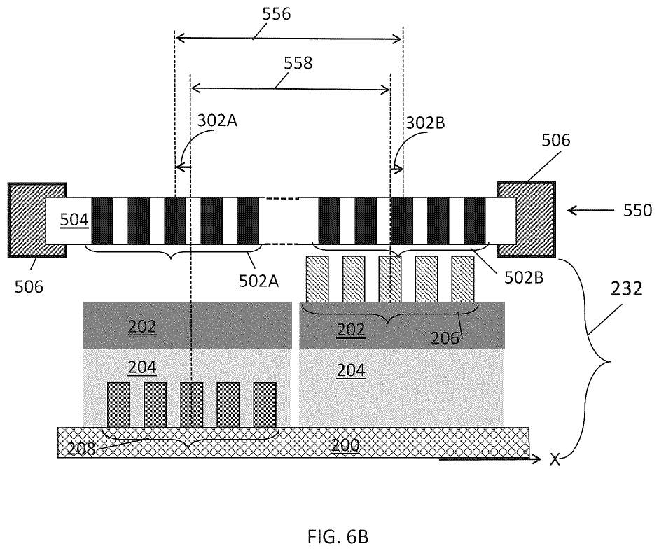

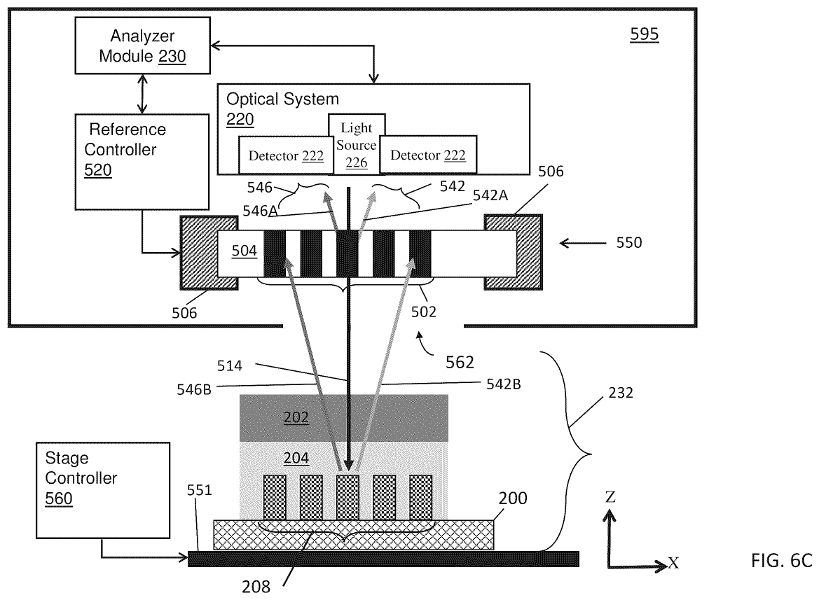

FIGS. 6A, 6B, and 6C illustrate measurement systems for determining an alignment error in accordance with some embodiments of the disclosure. FIG. 6A shows a cross-sectional view of an alignment sensor system 590 placed above, e.g., over, the substrate 232. The alignment sensor system 590 incudes the reference pattern module 550 that is coupled to the reference controller 520. As shown, the alignment sensor system 590 also includes an optical system 220 including the light sources 226 for generating incident beams 514 and 515. The optical system 220 also includes detectors 222 for detecting reflected light beams 546 and 542 that are back reflected from the alignment pattern 208 and reference pattern 502A. Also, the detectors 222 of the optical system 220 detect reflected light beams 544 and 548 that are reflected back from the alignment pattern 206 and reference pattern 502B. The reflected light beams from the alignment patterns 206 and 208 enter the alignment sensor system 590 through the opening 562.

FIG. 6A also shows, the substrate 232 is mounted on a stage 551, and the stage 551 is coupled to and controlled by a stage controller 560. The reference pattern module 550 of the alignment sensor system 590 is also mounted on top of and over the surface of the substrate 232 and in parallel with the stage 551. In some embodiments, the reference controller 520 moves the reference patterns 502A and 502B to specific locations such that the reference patterns 502A and 502B overlap, e.g., at least partially overlap, with the alignment patterns 206 and 208 of the substrate 232. In some embodiments, the reference pattern 502A overlaps with the alignment pattern 208 of the first layer 204 and the reference pattern 502B overlaps with the alignment pattern 206 of the resist layer 203. By measuring a relative position between the alignment pattern 208 and the reference pattern 502A and a relative position between the alignment pattern 206 and the reference pattern 502B, it is possible to measure an overlay error between the alignment pattern 206 and the alignment pattern 208 because the distance (e.g., center-to-center distance) between the reference pattern 502A and the reference pattern 502B is known or predetermined.

In some embodiments as shown in FIG. 6A, one of the light sources of the optical system 220 transmits an incident light beam 514 to the alignment patterns 208 and the reference pattern 502A that at least have an overlap in the X-direction. In some embodiments, the alignment pattern 208 and the reference pattern 502A have a same pitch. A portion of the incident light beam 514 is diffracted and reflected from the reference pattern 502A and produces the negative and positive first order diffraction beams that are inner portions of first order reflected diffraction beams 542 and 546, respectively. A remaining portion of the incident light beam 514 passes through the reference pattern 502A and is diffracted and reflected from the alignment pattern 208 and produces the negative and positive first order diffraction beams that are outer portions of first order reflected diffraction beams 542 and 546, respectively. The negative and positive reflected first order diffraction beams 542 and 546 that are reflected are detected by the detector 222 of the optical system 220.

FIG. 6A also shows the analyzer module 230 that is coupled to the optical system 220. The analyzer module 230 receives corresponding signals of the detected reflected first order diffraction beams 542 and 546 and performs an analysis on the corresponding signals to determine a first drift, e.g., a first overlay error, between the alignment pattern 208 and the reference pattern 502A. As described, in some embodiments, the wavelength of the light beam 514 is comparable with the pitch of the reference pattern 502A and the alignment patterns 208. Also, in some embodiments, the wavelength of the light beam 515 is comparable with the pitch of the reference pattern 502B and the alignment patterns 206. Thus, when the alignment patterns 208 and 206 have different pitches, two different light sources of the optical system 220 having different wavelengths are used to produce the light beams 514 and 515. In some embodiments, when the alignment patterns 208 and 206 have the same pitch, the same light source or two different light sources of the optical system 220 are used to produce the light beams 514 and 515.

In addition, as shown in FIG. 6A, one of the light sources of the optical system 220 transmits an incident light beam 515 to the alignment patterns 206 and the reference pattern 502B that at least have an overlap in the X-direction. In some embodiments, the alignment pattern 206 and the reference pattern 502B have a same pitch that is not the same as the pitches of the alignment pattern 208 and the reference pattern 502A. A portion of the incident light beam 515 is diffracted and reflected from the reference pattern 502B and produces the negative and positive first order diffraction beams that are inner portions of first order diffraction beams 544 and 548, respectively. A remaining portion of the incident light beam 515 passes through the reference pattern 502B and gets diffracted and reflected from the alignment pattern 206 and produces the negative and positive first order diffraction beams that are outer portions of first order diffraction beams 544 and 548, respectively. The negative and positive first order diffraction beams 544 and 548 that are reflected are detected by the detectors 222 of the optical system 220. The analyzer module 230 receives corresponding signals of the detected reflected first order diffraction beams 544 and 548 and performs an analysis on the corresponding signals to determine a second drift, e.g., a second overlay error, between the alignment pattern 206 and the reference pattern 502B. As described, a wavelength of the light beam irradiating the overlapped reference pattern 502B and the alignment pattern 206 and a wavelength of the light beam irradiating the overlapped reference pattern 502A and the alignment pattern 208 may be comparable to the pitches of the alignment patterns 206 and 208.

In some embodiments, the reference controller 520 has the information of the reference patterns 502A and 502B including a distance between the reference patterns 502A and 502B. In some embodiments, the overlap between the alignment patterns 208 and the reference pattern 502A is concurrent with the overlap between the alignment pattern 206 and the reference pattern 502B. In some embodiments, the reference pattern module includes reference patterns 502A and 502B that have a distance that is the expected distance between the alignment patterns 206 and 208. Thus, the analyzer module 230 may determine the overlay error between the alignment patterns 206 and 208 based on the first and second overlay errors.

In some embodiments, the overlap between the alignment pattern 208 and the reference pattern 502A is not concurrent with the overlap between the alignment pattern 206 and the reference pattern 502B. In addition, the analyzer module 230 receives the distance between the reference patterns 502A and 502B from the reference controller 520 and also receives the stage 551 movement from the stage controller 560, and receives the location of the reference pattern module 550 from the reference controller 520. Thus, the analyzer module 230 may determine the total overlay error between alignment patterns 206 and 208 based on the first and second overlay errors, the distance between the reference patterns 502A and 502B, and the movement distances of the reference pattern module 550 and/or the stage 551. In some embodiments, the reference pattern module 550 of the alignment sensor system 590 includes a layout pattern of a circuit. When the total overlay error is not more than a threshold value of about 0.1 percent, the layout pattern is projected onto a photo resist layer of the substrate 232 to produce a photo resist patterned layer.

FIG. 6B is consistent with FIG. 6A but only shows the reference pattern module 550 and the substrate 232. As shown, the reference pattern 502A is shifted by a shift distance 302A, e.g., an overlay error, in the negative X-direction with respect to the alignment pattern 208 of the substrate 232 and thus the shift distance 302A is a negative distance. In addition, the reference pattern 502B is shifted by a shift distance 302B, e.g., an overlay error, in the positive X-direction with respect to the alignment pattern 206 of the substrate 232 and thus the shift distance 302B is a positive distance. Thus, the total overlay shift distance (total overlay error) between the alignment patterns 206 and 208 is the difference between the distances 302A and 302B and because the distances 302A and 302B have different polarities the values add to each other.

In some embodiments, both of the distances 302A and 302B have the same polarity (not shown). The total overlay shift distance (total overlay error) between the alignment patterns 206 and 208 is the difference between the distances 302A and distance 302B and because the distances 302A and 302B have the same polarity the values are subtracted from each other.

In some embodiments, the alignment patterns 206 are part of a first layout pattern and the alignment patterns 208 are part of a second layout pattern. Thus, by determining, e.g., measuring, the total overlay error between the alignment patterns 206 and 208, the overlay error between the first layout pattern and the second layout pattern is determined.

As shown in FIG. 6B, the center-to-center distance between the reference patterns 502A and 502B is the distance 556 and the center-to-center distance between the alignment patterns 206 and 208 is a distance 558. Because the shift distances 302A and 302B have opposite polarities, a difference between the distances 556 and 558 has a value, which is a sum of the absolute values of the shift distances 302A and 302B.

FIG. 6C is consistent with FIG. 6A with the difference that the substrate 232 includes only the alignment pattern 208 and an alignment sensor system 595 that is consistent with the alignment sensor system 590 has only on reference pattern 502. The light source 226 generates the incident beam 514 and the detectors 222 receive and detect reflected first order diffraction beams 546B and 542B from the alignment pattern 208. Also, the detectors 222 receive and detect reflected first order diffraction beams 546A and 542A from the reference pattern 502 and the alignment pattern 208. The reflected beams of light from the alignment pattern 208 enter the alignment sensor system 595 through the opening 562. As described with respect to FIG. 6A, the analyzer module 230 may determine an overlay alignment error between the alignment patterns 208 and reference pattern. In some embodiments, the reference pattern module 550 of the alignment sensor system 595 includes a layout pattern of a circuit. When the overlay alignment error is not more than a threshold value of about 0.1 percent, the layout pattern is projected onto a photo resist layer of the substrate 232 to produce a photo resist patterned layer.

FIGS. 7A, 7B, 7C, 7D, and 7E illustrate alignment patterns for determining an overlay error in accordance with an embodiment of the present disclosure. FIG. 7A shows a top view of an alignment pattern 606 that is disposed on a substrate 610, e.g., a semiconductor or glass substrate. The alignment pattern 606 has two different patterns A1 and A2 that have a length 602 in the X-direction. The patterns A1 and A2 have two different respective widths W1 and W2 in the Y-direction. In some embodiments, a ratio of W2 to W1 is between about 2 and 10. The alignment pattern 606 has a pitch 604 in the X-direction. In some embodiments, the alignment pattern 606 is part of the layout pattern and is projected into the photo resist layer when the layout patterns of the circuits is projected. In some embodiments, the patterns A1 and A2 of the alignment pattern 606 are etched into the substrate. Therefore, the patterns A1 and A2 have a different depth compared to the substrate 610 and the reflected light from the patterns A1 and A2 have a different phase from the phase of the reflected light from the substrate 610. As shown, the alignment pattern 606 may have a repeating sub-pattern 620 that includes two A1 patterns and one A2 pattern that repeats in the X-direction.

FIG. 7B shows a cross-sectional view, perpendicular to the X-direction, of the substrate 610 that includes a cross-section of the alignment pattern 606. As shown, an etch stop layer 635 is deposited below the surface of the substrate 610 that limits a depth of the patterns A1 and A2 to a depth 612. FIG. 7B also shows the cross section of the repeating sub-pattern 620. In some embodiments, the patterns A1 and A2 having a depth relative to the top surface of the substrate, may cause a phase change in the reflected light from the patterns A1 and A2 compared to the reflected light from the surface of the substrate.

FIG. 7C shows a cross-sectional view, perpendicular to the X-direction, of the substrate 610 that includes a cross-section of the alignment pattern 607. The alignment pattern 607 includes similar patterns A3 with a depth 616, which has a bottom region 814. In some embodiments, an intensity of the reflected light I from alignment pattern on the substrate is shown by equation (1) below:

$$I = \frac{4}{{π}^{2}} {I}_{0} R {Sin}^{2} ( \frac{π r}{r + 1} ) {Sin}^{2} ( \frac{α}{2} ) \qquad ( 1 )$$

Where Iₒ is the intensity of incident light, R is the reflection coefficient of the substrate, r is the ratio between area of the alignment pattern on the top surface of the substrate to the area of the etched patterns at the bottom surface of the patterns A3. Also, α is the phase difference between the reflected light from the top surface of the substrate and the reflected light from the bottom surface of the patterns A3. Thus, r is the ratio of the area of regions 812 on top of the wafer to the area of the regions 814 at bottom of the patterns A3. In some embodiments, if the area of regions 812 is increased the reflected light intensity is increased. In some embodiments, if a beam of light 815 (e.g., a coherent beam of light) is incident on the alignment pattern 607, the reflected beams of light 820A and 820B respectively from the surface of the substrate 610 and from the bottom of the patterns A3 are out of phase but may be combined into a single beam of light with a phase. In some embodiments, since the incident beam of light covers some area around the alignment pattern on the top surface of the substrate 610, increasing the width of the patterns A3, which increase the area at the bottom of the patterns A3, increases the intensity of the reflected light I.

FIG. 7D is consistent with FIG. 7B with the difference that the substrate 610 of FIG. 7D does not have the etch stop layer 635. As a result, the patterns A1 and A2 of the repeating sub-pattern 620 have different depths. Pattern A1 has a depth 616 and the wider pattern A2 has a longer depth 618. Thus, the reflected light from the bottom of the patterns A1 and A2 incur different phase shifts. FIG. 7E is consistent with FIG. 7A with the difference that pattern A1 includes 3 smaller patterns A4 in the X-direction, however, the pitch 604 is not affected.

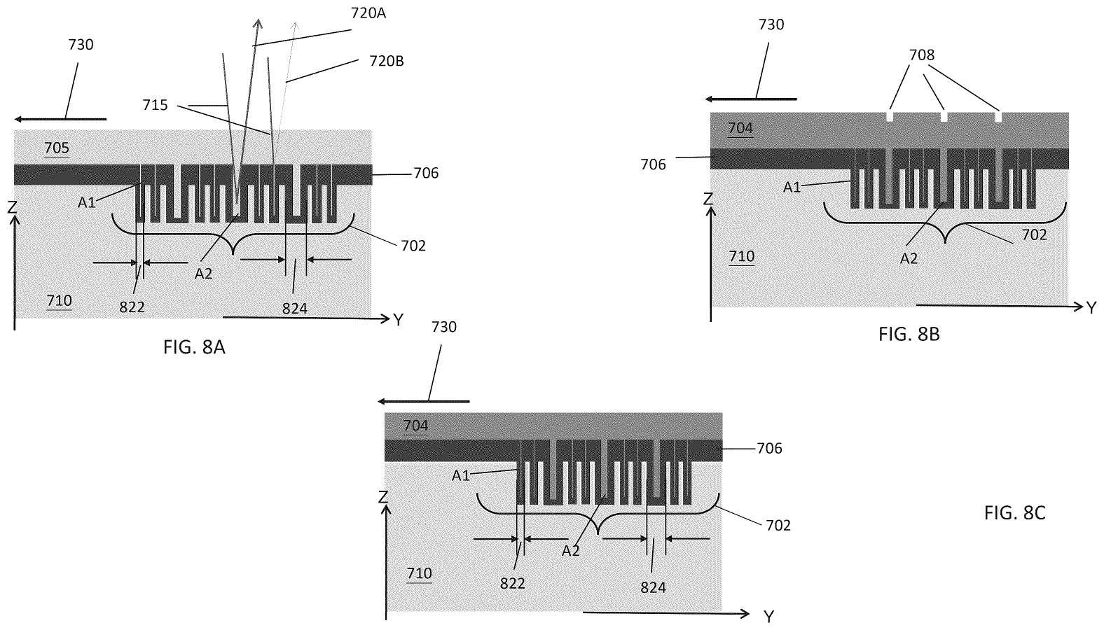

FIG. 8A, 8B, and 8C illustrate alignment patterns for determining an overlay error in accordance with some embodiments of the disclosure. FIG. 8A shows a substrate 710 having an alignment pattern 702 that includes the patterns A1 with the width 822 and the pattern A2 with the width 824 wider than the width 822. As shown, the alignment pattern is covered by a metal layer 706, which is semi-opaque to the incident light of lithography. In some embodiments, the metal layer is deposited because the alignment pattern is a part of the interconnection patterns for connection lines or the electrodes. In addition, a photo resist layer 705 is disposed over the metal layer 706. A beam of light 715 is incident on the surface of the substrate 710 and the alignment pattern 702. As shown, the beam of light 715 goes through the photo resist layer 705 and is reflected by the metal layer 706. In some embodiment, the metal layer reduces the intensity of the reflected light. As shown, a reflected beam of light 720A from the wider pattern A2 has a higher intensity compared to a reflected beam of light 720B from the pattern A1. Thus, increasing the width of pattern increases the intensity of the reflected light. FIGS. 8A, 8B, and 8C illustrate a peripheral region of the substrate 710 where the alignment pattern is formed. The circuit region is along a direction 730 on the substrate 710. In some embodiments, the alignment pattern 702 is covered by the photo resist layer 705 when patterning the substrate to deposit an isolation layer. The isolation layer is deposited over the metal layer to isolate the metal layer from the subsequent layers that are created over the metal layer. Thus, the isolation layer is also deposited over the alignment pattern 702.

FIG. 8B is consistent with FIG. 8A after the photo resist layer 705 is patterned and an isolation layer, e.g., an oxide layer 704, is disposed over the metal layer 706 including the metal layer that is over the alignment pattern 702. As shown, on top of the wider patterns A2 the isolation layer 104 is not flat and an indentation 708 is produced, while over the narrower patterns A1, the isolation layer 704 is flat. FIG. 8C is consistent with FIG. 8B with the difference that the top surface of the isolation layer is polished and the top surface of the isolation layer 704 is planarized. Thus, while increasing the width of the patterns increase the reflectivity, the width is increased in some embodiments to the point that the top surface of the isolation layer 704 is flat or can be planarized to become substantially flat, e.g., with a peak to peak difference of less than 0.1 mm for the substrate 710 over the alignment pattern 702.

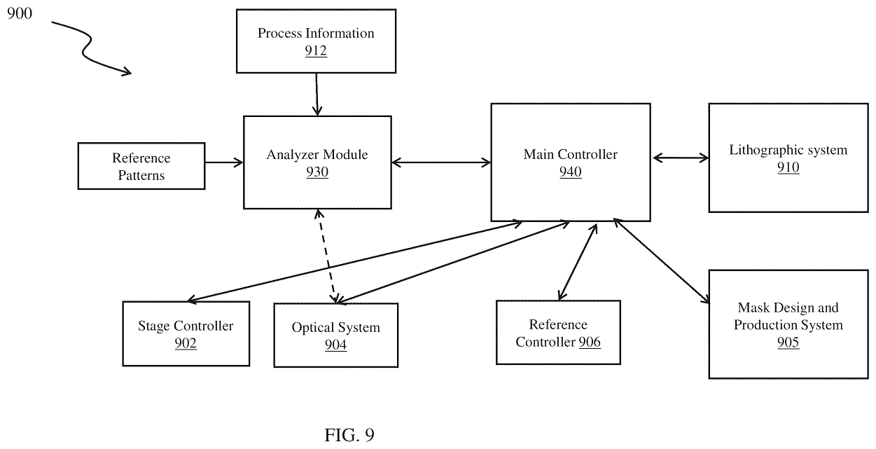

FIG. 9 illustrates a measurement system 900 for determining an overlay error in accordance with some embodiments of the disclosure. The system 900 includes an analyzer module 930 and a main controller 940 coupled to each other. The analyzer module 930, which is consistent with the analyzer module 230 of FIGS. 2B, 6A, and 6C receives the information, e.g., pitch, width, and distance, of reference patterns 502, 502A, and 502B that are on the reference pattern module 550. The analyzer module 930 may either directly connect to the optical system 904 or may connect to the optical system 904 via the main controller 940.

In some embodiments, the main controller 940 is coupled to a reference controller 906, the optical system 904, and a stage controller 902. In some embodiments, in reference to FIGS. 2B, 6A, and 6C, the optical system 904 is consistent with the optical system 220, the stage controller 902 is consistent with the stage controller 560, and the reference controller 906 is consistent with the reference controller 520. The optical system 904, which is controlled by the main controller 940, generates the incident light beams 214A, 514, and 515 of FIGS. 2B, 6A, and 6C. In addition, the optical system 904 receives the diffracted light from the alignment patterns and detects the diffracted light and generates corresponding signals of the detected diffracted light. The optical system 904 sends the corresponding signals of the detected diffracted light to the analyzer module 930 for analysis as described above with respect to FIGS. 6A and 6C to determine a drift between different alignment patterns of the substrate. FIG. 9 also includes a lithographic system 910 coupled to the main controller 940. In some embodiments, the main controller 940 commands the lithographic system to produce a photo resist pattern in a photo resist layer of a substrate, e.g., substrate 232 of FIGS. 2A and 3A. In addition, FIG. 9 includes mask design and production system 905. In some embodiments, modifying the width of patterns A1 and A2 of FIGS. 7A and 7E to increase the reflectivity is performed by computer simulation. In some embodiments, the main controller commands the mask design and production system 905 to perform the simulation and design the alignment patterns of a mask and then produce the layout pattern of the circuit and the alignment patterns associated with the layout patterns on a mask-blank.

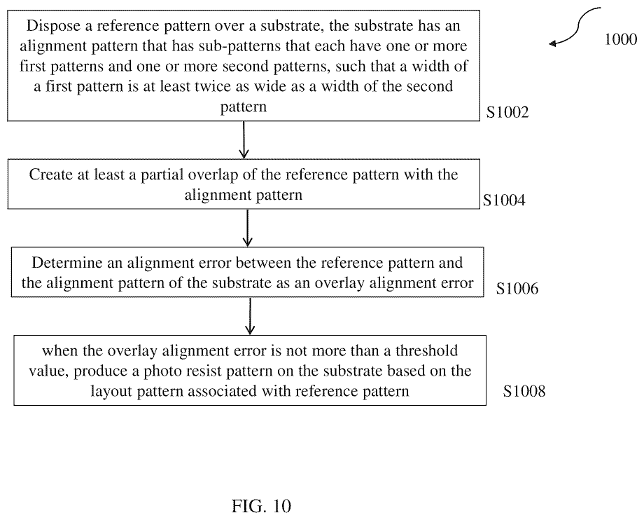

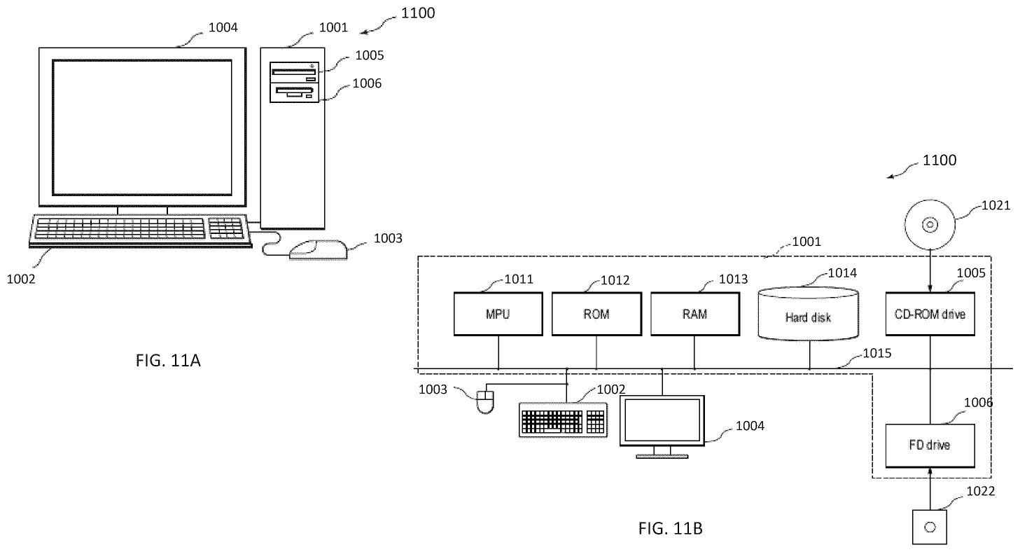

FIG. 10 illustrates a flow diagram of a process 1001 for determining an overlay error in accordance with some embodiments of the disclosure. The process 1001 may be performed by the measurement systems of FIGS. 6A, 6C, and 9. In some embodiments, a portion of the process 1001 is performed and/or is controlled by the computer system 1100 described below with respect to FIGS. 11A and 11B. The method includes the operation S1002 of disposing a reference pattern over a substrate. The substrate includes an alignment pattern that has sub-patterns that each have one or more first patterns and one or more second pattern, such that a width of a first pattern is at least twice as wide as a width of the second pattern. The patterns with multiple widths are described above with respect to FIGS. 7A, 7B, 7D, and 7E.

In some embodiments, the reference pattern is disposed by producing a photo resist layer over the substrate 232 and patterning the photo resist layer as shown in FIGS. 2A, 2B, and 3A. In some embodiments, as shown in FIGS. 2B, 6A, 6B, and 6C, the reference pattern is disposed by arranging the reference pattern module 550 so that it includes a reference pattern over the substate. In some embodiments, the reference pattern is disposed by arranging the alignment sensor system 590 that includes the reference pattern module 550 over the substrate 232.

In operation S1004, at least a partial overlap is created between the reference pattern and the alignment pattern of the substrate. As shown in FIG. 6C, an overlap is created between the first reference pattern 502 of the reference pattern module 550 and the alignment pattern 208 of the substrate 232.

In operation S1006, an alignment error between the reference pattern and alignment patterns is determined. As shown in FIG. 6C, the optical system 220 transmits the incident light beam 514 to the reference pattern 502 that is on top of the alignment pattern 208. The reflected first order reflected diffraction beams 542 and 546 from the first reference pattern 502 and from the alignment pattern 208 are detected by the detectors 222 of the optical system 220 and the detected signals are transmitted to the analyzer module 230. The analyzer module 230 determines, e.g., calculates, the layout error between the first alignment pattern 208 and the first reference pattern 502 based on the detected signals. In some embodiments, the reference pattern is a photo resist pattern disposed on top of a substrate, e.g., the alignment pattern 206 in photo resist layer 203 of FIG. 3A that is disposed over the first layer 204 that includes the alignment pattern 208. If the measured overlay error between the alignment patterns 206 and 208 is more than the threshold value, the photo resist layer 203 is removed and depositing and patterning the photo resist layer is repeated. As noted above, in some embodiments, the reference pattern module 550 that includes the reference pattern 502 includes a layout pattern of a circuit.

In step 1008, a photo resist pattern is produced on the substrate based on the layout pattern associated with reference pattern in the reference pattern module 550. The photo resist pattern is produced by a lithographic system 910 of FIG. 9.

FIGS. 11A and 11B illustrate an apparatus for determining an overlay error in accordance with some embodiments of the disclosure. FIG. 11A is a schematic view of a computer system 1100 that executes the process for determining the overlay error according to one or more embodiments as described above. All of or a part of the processes, method and/or operations of the foregoing embodiments can be realized using computer hardware and computer programs executed thereon. The operations include controlling an optical system and the light sources and detectors of the optical system, analyzing the light detected by the detectors, and controlling the movement of a stage holding a substrate and the movement of the reference pattern module to combine the diffracted light from the alignment patterns of the substrate 232 on the stage 551 and the alignment patterns of the reference pattern module 550. Thus, in some embodiments, the computer system 1100 provides the functionality of the analyzer module 930, the main controller 940, the stage controller 902, the reference controller 906, and a controller of the optical system 904. In FIG. 11A, a computer system 1100 is provided with a computer 1001 including an optical disk read only memory (e.g., CD-ROM or DVD-ROM) drive 1005 and a magnetic disk drive 1006, a keyboard 1002, a mouse 1003, and a monitor 1004.

FIG. 11B is a diagram showing an internal configuration of the computer system 1000. In FIG. 11B, the computer 1001 is provided with, in addition to the optical disk drive 1005 and the magnetic disk drive 1006, one or more processors 1011, such as a micro-processor unit (MPU), a ROM 1012 in which a program such as a boot up program is stored, a random access memory (RAM) 1013 that is connected to the processors 1011 and in which a command of an application program is temporarily stored and a temporary storage area is provided, a hard disk 1014 in which an application program, a system program, and data are stored, and a bus 1015 that connects the processors 1011, the ROM 1012, and the like. Note that the computer 1001 may include a network card (not shown) for providing a connection to a LAN.

The program for causing the computer system 1100 to execute the process for determining an overlay error of a semiconductor device in the foregoing embodiments may be stored in an optical disk 1021 or a magnetic disk 1022, which are inserted into the optical disk drive 1005 or the magnetic disk drive 1006, and transmitted to the hard disk 1014. Alternatively, the program may be transmitted via a network (not shown) to the computer 1001 and stored in the hard disk 1014. At the time of execution, the program is loaded into the RAM 1013. The program may be loaded from the optical disk 1021 or the magnetic disk 1022, or directly from a network. The program does not necessarily have to include, for example, an operating system (OS) or a third party program to cause the computer 1001 to execute the process for manufacturing the lithographic mask of a semiconductor device in the foregoing embodiments. The program may only include a command portion to call an appropriate function (module) in a controlled mode and obtain desired results.

As discussed above, when a metal layer is disposed over the substrate to generate the electrode, the metal layer covers the alignment patterns of the previously deposited circuit patterns. Thus, the alignment of the layers over the metal layer with the layer under the metal layer is difficult because the metal layer prevents a considerable percentage of the light to transmit through or reflect back. The transmitted light intensity may be increased. As discussed above the structure of the alignment patterns are modified such that the reflected light from the alignment pattern is increased while keeping the layers deposited over the metal layer flat without the extra steps of either masking the alignment patterns when producing the metal layer, or creating high aspect ratio alignment marks that result in poor planarization of the subsequent layers.

It will be understood that not all advantages have been necessarily discussed herein, no particular advantage is required for all embodiments or examples, and other embodiments or examples may offer different advantages.

According to some embodiments of the present disclosure, an alignment method includes disposing a reference pattern over a substrate. The reference pattern is included in a reference pattern module that includes a layout pattern associated with reference pattern. The substrate includes an alignment pattern in a first location. The alignment pattern includes two or more sub-patterns extending in a first interval along a first direction and being arranged with a first pitch in a second direction crossing the first direction. Each sub-pattern includes one or more first patterns and one or more second patterns, and a first width of a first pattern in the first direction is at least twice as wide as a second width of the second pattern in the first direction. The method further includes at least partially overlapping the reference pattern with the alignment pattern and determining an alignment error between the reference pattern and the alignment pattern of the substrate as an overlay alignment error. The method also includes that when the overlay alignment error is not more than a threshold value, producing a photo resist pattern on the substrate based on the layout pattern associated with reference pattern. In an embodiment, the first pattern has a first depth and the second pattern has a second depth, and wherein the first and second depth are different. In an embodiment, the method further includes disposing a metal layer over the alignment pattern of the substrate, disposing a photo resist layer over the metal layer such that the first width of the first pattern and the second width of the second pattern are selected to maintain a top surface of the photo resist layer substantially flat, the alignment pattern is under the photo resist layer, and determining the alignment error between the reference pattern and the alignment pattern under the photo resist layer. In an embodiment, the method further includes disposing a metal layer over the alignment pattern of the substrate, disposing an isolation material layer over the metal layer, wherein the reference pattern is disposed over the isolation material layer, determining the alignment error between the reference pattern and the alignment pattern, and planarizing a top surface of the isolation material layer before disposing the reference pattern over the substrate. In an embodiment, the method further includes. In an embodiment, each second pattern includes two or more equally sized and spaced fourth patterns extending in a length of the second pattern along the second direction. In an embodiment, the reference pattern is stored in a reference pattern module, the method further includes arranging a ratio of the first width of the first pattern to the second width of the second pattern such that, during lithography, an intensity of a reflected light from the first pattern is at least twice an intensity of a reflected light from the second pattern. In an embodiment, the method further includes that prior to the at least partially overlapping, generating the reference pattern in the reference pattern module, wherein the reference pattern has a second pitch in the second direction equal to the first pitch of the alignment pattern of the substrate.

According to some embodiments of the present disclosure, an alignment method includes disposing a reference pattern module over a substrate. The reference pattern module includes a layout pattern associated with reference pattern. The substrate includes a first alignment pattern in a first location and a second alignment pattern separate from the first alignment pattern in a second location. The reference pattern module includes a first reference pattern and a second reference pattern separate from the first reference pattern. the first alignment pattern includes a first plurality of first sub-patterns extending in a first interval along a first direction and arranged with a first pitch in a second direction crossing the first direction. At least one of a first sub-pattern or a second sub-pattern includes one or more first patterns and one or more second patterns such that a first width of a first pattern in the first direction is at least twice as wide as a second width of the second pattern in the first direction. The method further includes creating at least a first partial overlap of the first reference pattern with the first alignment pattern under the reference pattern module and concurrently with creating the first partial overlap, creating at least a second partial overlap of the second reference pattern with the second alignment pattern under the reference pattern module. The method also includes determining a first alignment error between the first reference pattern of the reference pattern module and the first alignment pattern of the substrate and determining a second alignment error between the second reference pattern of the reference pattern module and the second alignment pattern of the substrate. The method includes determining a total overlay error between the first and second alignment patterns of the substrate based on the first and second alignment errors and when the total overlay error is not more than a threshold value, producing a photo resist pattern on the substrate based on the layout pattern associated with reference pattern. In an embodiment, the determining the total overlay error between the first alignment pattern and the second alignment pattern comprises determining an algebraic sum of the first and second alignment errors. In an embodiment, the determining the first alignment error includes applying a first beam of light over the first partial overlap of the first reference pattern and the first alignment pattern and analyzing diffracted light from the first alignment pattern and the first reference pattern to determine the first alignment error. In an embodiment, the determining the second alignment error include applying a second beam of light over the second partial overlap of the second reference pattern and the second alignment pattern and analyzing diffracted light from the second alignment pattern and the second reference pattern to determine the second alignment error. In an embodiment, the method further includes that prior to the creating the first partial overlap, generating the first reference pattern and the second reference pattern in the reference pattern module. The first reference pattern has a third pitch in the second direction equal to the first pitch of the first alignment pattern of the substrate, and the second reference pattern has a fourth pitch in the second direction equal to the second pitch of the second alignment pattern of the substrate. In an embodiment, the method further includes that prior to the creating the first partial overlap and the second partial overlap, disposing a photo resist layer or a metal layer over the first and second alignment patterns of the substrate. The first alignment error and the second alignment error are determined when the photo resist layer or the metal layer is disposed over at least one of the first and second alignment patterns of the substrate. In an embodiment, the first sub-pattern includes a repeating pattern in the first direction that includes one or more first patterns and one or more second patterns.

According to some embodiments of the present disclosure, an overlay error measurement system includes a controller programmed to perform the steps to dispose a reference pattern over a substrate the alignment pattern include two or more sub-patterns extending in a first interval along a first direction and being arranged with a first pitch in a second direction crossing the first direction. Each sub-pattern includes one or more first patterns and one or more second patterns. A first width of a first pattern in the first direction is at least twice as wide as a second width of the second pattern in the first direction. The controller programmed to perform the step to at least partially overlap the reference pattern with the alignment pattern, and determine an alignment error between the reference pattern and the alignment pattern of the substrate as an overlay alignment error. In an embodiment, prior to disposing the reference pattern over the substrate the controller is programmed to generate an etch stop layer under a top surface of the substrate. A first depth of the first pattern and a second depth of the second pattern are limited to the etch stop layer. In an embodiment, prior to disposing the reference pattern over the substrate the controller is programmed to dispose a metal layer over the alignment pattern of the substrate, and dispose a photo resist layer over the metal layer such that the determining the alignment error is performed when the metal layer and the photo resist layer are over the alignment pattern. In an embodiment, prior to disposing the reference pattern over the substrate the controller is programmed to dispose a metal layer over the alignment pattern of the substrate, and dispose an isolation layer over the metal layer such that the determining the alignment error is performed when the metal layer and the isolation layer are over the alignment pattern. In an embodiment, wherein the controller is programmed to arrange a ratio of the first width of the first pattern to the second width of the second pattern such that, during a lithographic process, an intensity of a reflected light from the first pattern is at least twice an intensity of a reflected light from the second pattern. In an embodiment, the system further includes a non-transitory memory coupled to the controller such that the controller receives instructions to perform the steps from the non-transitory memory,

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An overlay error measurement system, comprising:
a controller programmed to perform steps to:
dispose a reference pattern over a substrate, wherein:
the substrate comprises an alignment pattern in a first location, and
the alignment pattern comprises two or more sub-patterns extending in a first interval along a first direction and being arranged with a first pitch in a second direction crossing the first direction, wherein each sub-pattern comprises one or more first patterns and one or more second patterns, and wherein a first width of a first pattern in the first direction is at least twice as wide as a second width of a second pattern in the first direction;
at least partially overlap the reference pattern with the alignment pattern; and
determine an alignment error between the reference pattern and the alignment pattern of the substrate as an overlay alignment error.

2. The overlay error measurement system of claim 1, wherein prior to disposing the reference pattern over the substrate, the controller is programmed to:
control forming an etch stop layer under a top surface of the substrate, wherein a first depth of the first pattern and a second depth of the second pattern are limited to the etch stop layer.

3. The overlay error measurement system of claim 1, wherein prior to disposing the reference pattern over the substrate, the controller is programmed to:
control forming a metal layer over the alignment pattern of the substrate; and
control forming a photo resist layer over the metal layer, wherein determining the alignment error is performed when the metal layer and the photo resist layer are over the alignment pattern.

4. The overlay error measurement system of claim 1, wherein prior to disposing the reference pattern over the substrate, the controller is programmed to:
control forming a metal layer over the alignment pattern of the substrate; and
control forming an isolation layer over the metal layer, wherein determining the alignment error is performed when the metal layer and the isolation layer are over the alignment pattern.

5. The overlay error measurement system of claim 1, wherein prior to disposing the reference pattern over the substrate, the controller is programmed to:
arrange a ratio of the first width of the first pattern to the second width of the second pattern such that, during a lithographic process, an intensity of a reflected light from the first pattern is at least twice an intensity of a reflected light from the second pattern.

6. The overlay error measurement system of claim 1, further comprising:
a non-transitory memory coupled to the controller,
wherein the controller is configured to receive instructions to perform the steps from the non-transitory memory.

7. A system, comprising:
a controller configured to perform operations comprising:
positioning a reference pattern over a first alignment pattern formed in a substrate, wherein the reference pattern and the first alignment pattern comprise two or more sub-patterns, the two or more sub-patterns comprising a first pattern having a first depth and a second pattern having a second depth that is different from the first depth;
causing a light beam to impinge on the reference pattern and the first alignment pattern;
measuring at least one of diffracted light or reflected light from the reference pattern and the first alignment pattern;
determining an overlay alignment error between the reference pattern and the first alignment pattern based on the at least one of the diffracted light or the reflected light; and
when the overlay alignment error is not more than a threshold value, producing a photo resist pattern on the substrate based on a layout pattern associated with the reference pattern.

8. The system of claim 7, wherein measuring the diffracted light further comprises:
measuring a first signal representing a positive first order diffracted light component;
measuring a second signal representing a negative first order diffracted light component;
subtracting the second signal from the first signal to generate an asymmetry function; and
determining a shift distance between the reference pattern and the first alignment pattern based on the asymmetry function.

9. The system of claim 7, wherein a first width of the first pattern in a first direction is at least twice as wide as a second width of the second pattern in the first direction.

10. The system of claim 9, wherein:
a ratio of the first width of the first pattern to the second width of the second pattern is such that, during lithography, a first intensity of a first reflected light from the first pattern is at least twice a second intensity of a second reflected light from the second pattern.

11. The system of claim 7, wherein:
the substrate further comprises a second alignment pattern; and
the reference pattern further comprises a first reference pattern in a first location and a second reference pattern separate from the first reference pattern in a second location;
wherein the controller is configured to perform further operations comprising:
positioning the first reference pattern over the first alignment pattern,
positioning the second reference pattern over the second alignment pattern,
determining a first alignment error between the first reference pattern and the first alignment pattern;
determining a second alignment error between the second reference pattern and the second alignment pattern;
determining a total overlay error based on the first alignment error and the second alignment error; and
determining the overlay alignment error to be the total overlay error.

12. The system of claim 11, further comprising determining the total overlay error to be an algebraic sum of the first alignment error and the second alignment error.

13. The system of claim 11, wherein prior to disposing the reference pattern over the substrate, the controller is configured to perform operations further comprising:
controlling forming an etch stop layer under a top surface of the substrate, wherein a first depth of the first pattern and a second depth of the second pattern are limited to the etch stop layer.

14. The system of claim 11, wherein prior to disposing the reference pattern over the substrate, the controller is configured to perform operations further comprising:
controlling formation of a metal layer over the first alignment pattern and the second alignment pattern; and
controlling formation of a photo resist layer over the metal layer, wherein determining the overlay alignment error is performed when the metal layer and the photo resist layer are over the first alignment pattern and the second alignment pattern.

15. The system of claim 11, wherein prior to positioning the first reference pattern over the first alignment pattern and positioning the second reference pattern over the second alignment pattern, the controller is configured to perform operations further comprising:
controlling formation of a metal layer over the first alignment pattern and the second alignment pattern; and
controlling formation of an isolation layer over the metal layer, wherein determining the overlay alignment error is performed when the metal layer and the isolation layer are over the first alignment pattern and the second alignment pattern.

16. A system comprising a controller configured to perform operations comprising:
disposing a reference pattern over a substrate,
wherein:
the system comprises a reference pattern module including a reference pattern that comprises a layout pattern associated with the reference pattern;
the substrate comprises an alignment pattern in a first location; and
the alignment pattern comprises two or more sub-patterns within a single layer extending in a first interval along a first direction and being arranged with a first pitch in a second direction crossing the first direction, wherein each sub-pattern comprises one or more first patterns and one or more second patterns, and wherein a first width of a first pattern in the first direction is at least twice as wide as a second width of a second pattern in the first direction, and the first pattern has a first depth and the second pattern has a second depth, and wherein the first depth and the second depth are different;
at least partially overlapping the reference pattern with the alignment pattern;
determining an alignment error between the reference pattern and the alignment pattern of the substrate as an overlay alignment error; and
when the overlay alignment error is not more than a threshold value, producing a photo resist pattern on the substrate based on the layout pattern associated with reference pattern.

17. The system of claim 16, wherein the first depth is greater than the second depth.

18. The system of claim 16, wherein the controller is configured to perform further operations comprising:
disposing a metal layer over the alignment pattern of the substrate;
disposing a photo resist layer over the metal layer and the alignment pattern, wherein the first width of the first pattern and the second width of the second pattern are selected to maintain a top surface of the photo resist layer substantially flat;
determining the alignment error between the reference pattern and the alignment pattern under the photo resist layer.

19. The system of claim 16, wherein the controller is configured to perform further operations comprising:
disposing a metal layer over the alignment pattern of the substrate;
disposing an isolation material layer over the metal layer, wherein the reference pattern is disposed over the isolation material layer;
determining the alignment error between the reference pattern and the alignment pattern; and
planarizing a top surface of the isolation material layer before disposing the reference pattern over the substrate.

20. The system of claim 16, wherein each second pattern comprises two or more equally sized and spaced fourth patterns extending in a length of the second pattern along the second direction.
